(19) United States
(12) Patent Application Publication
(10) Pub. No.: US 2015/0173220 A1
(43) Pub. Date: Jun. 18, 2015

(54) Cradle for Electronic Devices

(71) Applicant: Jong Hun Kim, Ulsan (KR)

(72) Inventor: Jong Hun Kim, Ulsan (KR)

(21) Appl. No.: 14/558,464

(22) Filed: Dec. 2, 2014

(30) Foreign Application Priority Data
Dec. 18, 2013 (KR) 20-2013-0010548

(51) Int. Cl. H05K 5/02; F16M 11/38

(52) U.S. Cl. CPC H05K 5/0226; H05K 5/0204; F16M 11/38

(57) ABSTRACT

The present invention relates to a cradle for electronic devices. The cradle for electronic devices includes: a pair of supporters having cut portions formed in the length direction; a horizontal plate joined to the supporters in such a manner that one end and the other end of the horizontal plate are inserted into insertion grooves which are opposed to each other at predetermined positions of upper sides of the supporters; and a support plate having hinge parts which are disposed at predetermined positions of both sides and are joined to hinge holes formed to be connected with the cut portions at predetermined positions in the length direction of the supporters.

### CROSS-REFERENCE TO RELATED APPLICATION

This application is based on and claims priority from Korean Utility Model Application No. 20-2013-0010548 filed on Dec. 18, 2013 in the Korean Intellectual Property Office, the disclosure of which is incorporated herein in its entirety by reference.

### BACKGROUND OF THE INVENTION

1. Field of the Invention

The present invention relates to a cradle for electronic devices, and more particularly, to a cradle for electronic devices which holds an electronic device around a user to use immediately and has a function as an ornament due to its beautiful appearance.

2. Background of the Related Art

In today's society, people use various portable electronic devices, such as smart phones, tablet PCs, and so on.

Such portable electronic devices have enhanced multimedia functions, such as videos, DMB receiving functions, in order to improve portability, and hence, long-term uses of the electronic devices become frequent.

However, such portable electronic devices go with physical fatigue and restrict physical activities because the users carry and use the electronic devices with hands.

Moreover, the users may lose the portable electronic devices through carelessness, let fall the portable electronic device by mistake to damage the portable electronic device, and hence, such portable electronic devices demand great caution in carrying and use.

In relation with the above, some vehicles have a holder for holding the portable electronic devices, but the holder is limited to vehicles in a range of use and it is impossible to move the holder because it is a fixed type. Furthermore, excepting a charger for charging a battery, because there is no holding means for stably holding the electronic devices at home or in a business office, the user has to rebuy the holding means when buy a new electronic device because of loss or damage of the previous electronic device, and hence, it increases the economic burden.

In order to solve the problems, Korean Patent No. 10-0713495 discloses a “standing device for portable electronic devices”.

The conventional standing device for portable electronic devices has a structure that a fixing member supports a portable electronic device while a link member is separated from a support when a user adjusts the position of a moving member slidably connected to the support.

However, the conventional standing device for portable electronic devices has several disadvantages in that it is frequently broken down and damaged due to its complicated structure and in that the user has to directly adjust the position of the moving member every time the user uses in such a manner that the fixing member supports the portable electronic device.

### SUMMARY OF THE INVENTION

Accordingly, the present invention has been made in view of the above-mentioned problems occurring in the prior art, and it is an object of the present invention to provide a cradle for electronic devices which has a simple structure and can easily hold the electronic device at a wanted angle so as to provide convenience in use.

To accomplish the above object, according to the present invention, there is provided a cradle for electronic devices including: a pair of supporters having cut portions formed in the length direction; a horizontal plate joined to the supporters in such a manner that one end and the other end of the horizontal plate are inserted into insertion grooves which are opposed to each other at predetermined positions of upper sides of the supporters; and a support plate having hinge parts which are disposed at predetermined positions of both sides and are joined to hinge holes formed to be connected with the cut portions at predetermined positions in the length direction of the supporters.

According to the present invention, the support plate selectively stands erect relative to the horizontal plate when the hinge parts are inserted into fixing grooves formed at the lower portions of the hinge holes or is located at the lower portion of the horizontal plate when the hinge parts slide along the cut portions.

According to the present invention, the horizontal plate comprises a plurality of support protrusions disposed at the upper side thereof and spaced apart from each other at predetermined intervals and one of the support protrusions is higher than the other support protrusions.

According to the present invention, the support plate comprises a cut hole formed at an end portion of one side, and the cut hole is inserted into a retaining protrusion formed at a predetermined position of the lower side of the horizontal plate when the support plate slides along the cut portion, so as to restrict a sliding movement of the support plate.

According to the present invention, each of the supporters comprises: an extension part which is formed at an end portion of one side and has a retaining groove, and the support plate comprises a pair of retaining portions which are formed symmetrically at both end portions of the upper side thereof to be caught to the retaining groove when the support plate is located at the lower portion of the horizontal plate.

According to the present invention, the supporters comprises a pair of protruding portions which are formed at one side of each supporter to face each other to fix the position of the support plate when the hinge parts are inserted into the fixing grooves formed at the lower portions of the hinge holes to make the support plate stand erect relative to the horizontal plate, and the support plate comprises a pair of passing grooves which are formed at predetermined positions of both sides in the length direction so as to make the protruding portions pass through the passing grooves when the support plate rotates to stand erect relative to the horizontal plate.

According to the present invention, the extension part comprises a flange portion protruding from one side of the extension part to support the lower side of the support plate when the support plate slides along the cut portion and is located at the lower portion of the horizontal plate.

According to the present invention, a lower plate which has a nonslip pad disposed on the lower side is joined to the lower portions of the supporters.

According to the present invention, the cradle for electronic devices has a simple structure, can easily hold the electronic device at a wanted angle so as to provide convenience in use, and has a function as an ornament due to its beautiful appearance.

### BRIEF DESCRIPTION OF THE DRAWINGS

The above and other objects, features and advantages of the present invention will be apparent from the following detailed description of the preferred embodiments of the invention in conjunction with the accompanying drawings, in which:

FIG. 1 is a perspective view of a cradle for electronic devices according to an embodiment of the present invention;

FIG. 2 is an exploded perspective view of the cradle for electronic devices according to the embodiment of the present invention;

FIG. 3 is a view showing an operated state of the cradle for electronic devices according to the embodiment of the present invention; and

FIG. 4 is a view showing a use state of the cradle for electronic devices according to the embodiment of the present invention.

### DETAILED DESCRIPTION OF THE PREFERRED EMBODIMENT

Hereinafter, an explanation on a cradle for electronic devices according to the present invention will be in detail given with reference to the attached drawing. In the description, the thicknesses of the lines or the sizes of the components shown in the drawing may be magnified for the clarity and convenience of the description.

Further, the terms as will be discussed later are defined in accordance with the functions of the present invention, but may be varied under the intention or regulation of a user or operator. Therefore, they should be defined on the basis of the whole scope of the present invention.

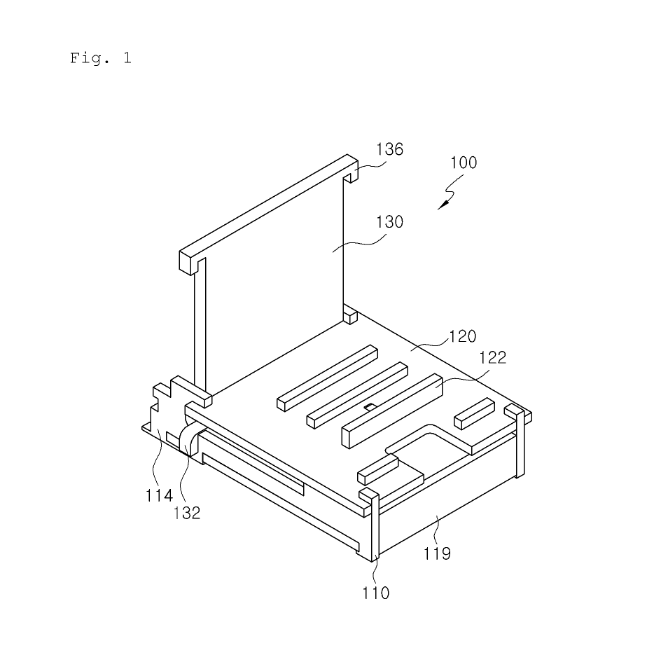

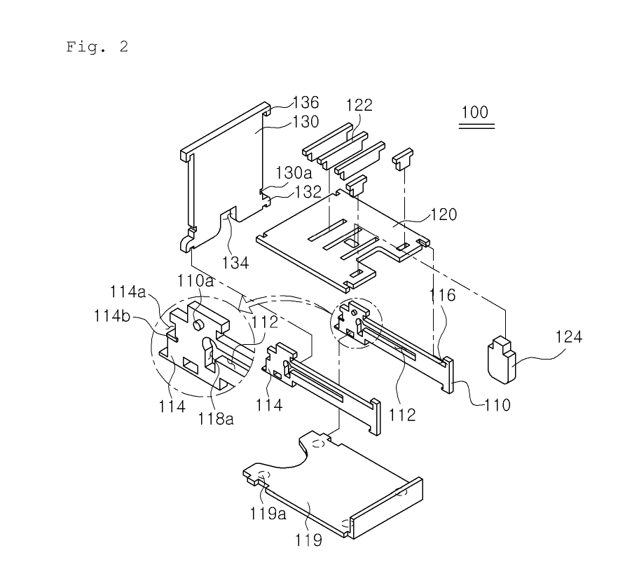

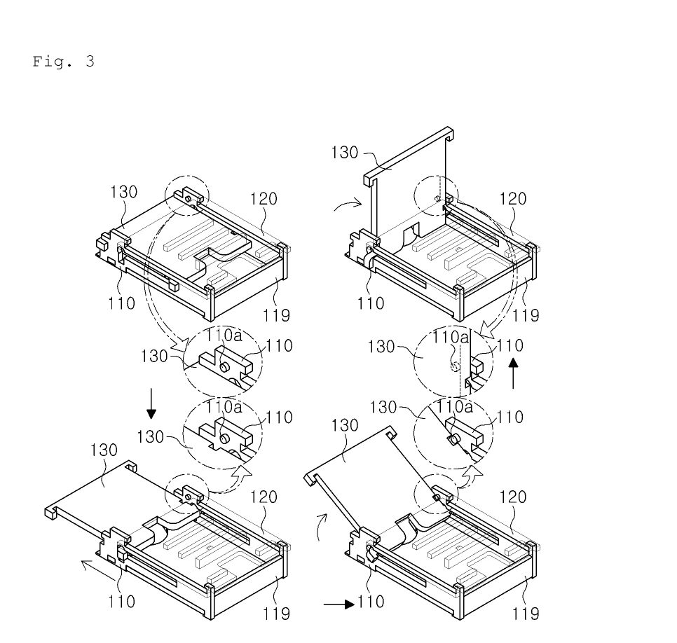

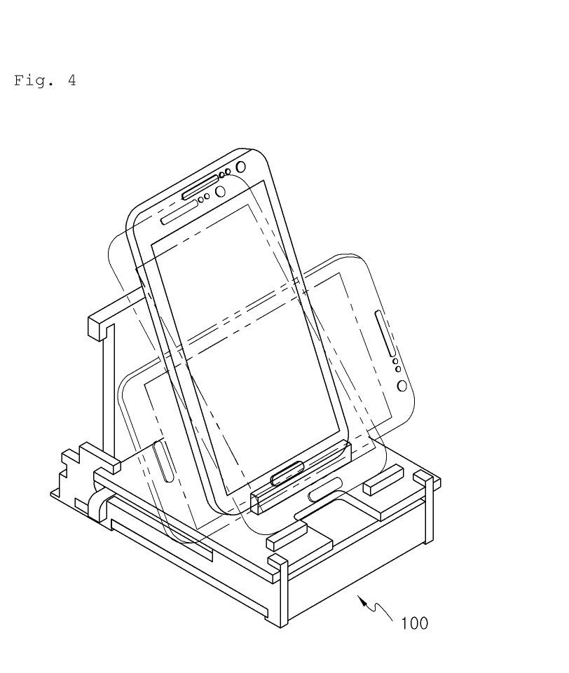

FIG. 1 is a perspective view of a cradle for electronic devices according to an embodiment of the present invention, FIG. 2 is an exploded perspective view of the cradle for electronic devices according to the embodiment of the present invention, FIG. 3 is a view showing an operated state of the cradle for electronic devices according to the embodiment of the present invention, and FIG. 4 is a view showing a use state of the cradle for electronic devices according to the embodiment of the present invention.

Referring to FIGS. 1 to 4, the cradle 100 for electronic devices according to the embodiment of the present invention includes a pair of supporter 110, a horizontal plate 120, and a support plate 130.

The supporters 110 are symmetric in shape, and each of the supporters 110 has a cut portion 112 formed in the length direction.

Each of the supporters 110 further has a hinge hole 118 formed at a predetermined position of the length direction to be connected with the cut portion 112.

Here, the supporters 110 which face each other have a pair of protruding portions 110a formed at one side of each supporter to face each other. The protruding portions 110a support the support plate 130 to be fixed in position when hinge parts 132 of the support plate 130 are inserted into fixing grooves 118a formed at the lower portions of the hinge holes 118 and the support plate 130 stands erect relative to the horizontal plate 120.

Each of the supporters 110 has an extension part 114 which is formed at an end portion of one side and has a retaining groove 114a, and the extension part 114 balances weight so that the holder 110 does not go down when the electronic device is held on the cradle 100.

The extension part 114 has a flange portion 114b protruding from one side, and the flange portion 114b supports the lower side of the support plate 130 when the support plate 130 slides along the cut portion 112 and is located at the lower portion of the horizontal plate 120, such that the support plate 130 moves smoothly along the cut portion 112.

A lower plate 119 is connected to lower portions of the supporters 110 in order to increase a binding force when the supporters 110 are joined with the horizontal plate 120.

Additionally, the lower plate 119 has a nonslip pad 119a disposed on the lower side thereof in order to prevent the holder 110 from sliding.

The horizontal plate 120 is joined to the supporters 110 in such a manner that one end and the other end of the horizontal plate 120 are inserted into insertion grooves 116 which are opposed to each other at predetermined positions of upper sides of the supporters 110.

Moreover, the horizontal plate 120 has a plurality of support protrusions 122 which are formed at the upper side thereof and are spaced apart from each other at predetermined intervals in the length direction. The support protrusions 122 are provided to adjust an angle of the electronic device hold on the cradle 100.

In this instance, preferably, one of the support protrusions 122 is higher than the other support protrusions, more concretely, the support protrusion which is located at the outermost position of the horizontal plate 120 is formed to be higher than the other support protrusions, in order to prevent the electronic device from being separated from the cradle 100 when the lower side of the electronic device held on the cradle 100 is supported on the support protrusion located at the outermost position of the horizontal plate 120.

The support plate 130 is rotatably joined to the hinge holes 118 connected with the cut portions 112 formed in the length direction of the supporters 110 so as to support one side of the upper part of the electronic device held on the cradle 100.

The support plate 130 has hinge parts 132 disposed at predetermined positions of both sides thereof. The hinge parts 132 selectively make the support plate 130 stand erect relative to the horizontal plate 120 by being inserted into the fixing grooves 118a formed at predetermined positions of the inner circumferential surfaces of the hinge holes 118 in the height direction of the supporter 110 or make the support plate 130, which slides along the cut portions 112, be located at the lower portion of the horizontal plate 120.

Furthermore, the support plate 130 has a cut hole 134 formed at an end portion of one side, and the cut hole 134 is inserted into a retaining protrusion 124 formed at a predetermined position of the lower side of the horizontal plate 120 when the support plate 130 slides along the cut portion 112, so as to restrict a sliding movement of the support plate 130.

Additionally, the support plate 130 has a pair of retaining portions 136 formed symmetrically at both end portions of the upper side thereof. The retaining portions 136 are retained to the retaining grooves 114a disposed in the extension parts 114 of the supporters 110 when the support plate 130 slides along the cut portions 112 and is located at the lower portion of the horizontal plate 120, so as to prevent the supporters 110 from moving in the height direction.

The support plate 130 has a pair of passing grooves 130a formed at predetermined positions of both sides in the length direction. The passing grooves 130a prevent the support plate 130 from being caught to the protruding portions 110a of the supporters 110 when the support plate 130 rotates to stand erect relative to the horizontal plate 120, such that the support plate 130 can rotate smoothly.

Hereinafter, a use state of the cradle for electronic devices according to the embodiment of the present invention will be described.

First, in a case that an electronic device is held on the cradle 100 for electronic devices, the support plate 130 is rotated in one side direction relative to the horizontal plate 120, and then, the hinge parts 132 located at the predetermined positions of both sides of the support plate 130 are inserted into the fixing grooves 118a of the hinge holes 118, such that the support plate 130 stands erect relative to the horizontal plate 120. After that, the lower side of the electronic device is supported by one of the support protrusions 122 disposed at the upper side of the horizontal plate 120, and then, one side of the electronic device is supported on the support plate 130, so that the user can use the electronic device on the cradle.

In this instance, the support plate 130 is supported and fixed in position by the protruding portions 110a formed at the sides of the supporters 110.

Furthermore, in a case that the cradle 100 is not used, the support plate 130 slides along the cut portions 112 of the supporters 110 and is located at the lower portion of the horizontal plate 120, and then, the cut hole 134 formed at the end portion of one side of the support plate 130 is inserted into the retaining protrusion 124 disposed at the predetermined position of the lower side of the horizontal plate 120. After that, the retaining portions 136 formed symmetrically at both end portions of the other side of the support plate 130 are caught to the retaining grooves 114a of the extension parts 114 of the supporters 110, such that the cradle 100 for electronic devices can be kept in safety.

Therefore, the cradle for electronic devices has a simple structure, can easily hold the electronic device at a wanted angle so as to provide convenience in use, and has a function as an ornament due to its beautiful appearance.

While the present invention has been described with reference to the preferred embodiment, it is to be appreciated that those skilled in the art can change or modify the embodiment without departing from the technical scope and spirit of the present invention described in the claims.

What is claimed is:

1. A cradle for electronic devices comprising:
a pair of supporters having cut portions formed in the length direction;
a horizontal plate joined to the supporters in such a manner that one end and the other end of the horizontal plate are inserted into insertion grooves which are opposed to each other at predetermined positions of upper sides of the supporters; and
a support plate having hinge parts which are disposed at predetermined positions of both sides and are joined to hinge holes formed to be connected with the cut portions at predetermined positions in the length direction of the supporters.

2. The cradle for electronic devices according to claim 1, wherein the support plate selectively stands erect relative to the horizontal plate when the hinge parts are inserted into fixing grooves formed at the lower portions of the hinge holes or is located at the lower portion of the horizontal plate when the hinge parts slide along the cut portions.

3. The cradle for electronic devices according to claim 1, wherein the horizontal plate comprises a plurality of support protrusions disposed at the upper side thereof and spaced apart from each other at predetermined intervals and one of the support protrusions is higher than the other support protrusions.

4. The cradle for electronic devices according to claim 1, wherein the support plate comprises a cut hole formed at an end portion of one side, and the cut hole is inserted into a retaining protrusion formed at a predetermined position of the lower side of the horizontal plate when the support plate slides along the cut portion, so as to restrict a sliding movement of the support plate.

5. The cradle for electronic devices according to claim 1, wherein each of the supporters comprises an extension part which is formed at an end portion of one side and has a retaining groove, and the support plate comprises a pair of retaining portions which are formed symmetrically at both end portions of the upper side thereof to be caught to the retaining grooves when the support plate is located at the lower portion of the horizontal plate.

6. The cradle for electronic devices according to claim 2, wherein the supporters comprises a pair of protruding portions which are formed at one side of each supporter to face each other to fix the position of the support plate when the hinge parts are inserted into the fixing grooves formed at the lower portions of the hinge holes to make the support plate stand erect relative to the horizontal plate, and the support plate comprises a pair of passing grooves which are formed at predetermined positions of both sides in the length direction so as to make the protruding portions pass through the passing grooves when the support plate rotates to stand erect relative to the horizontal plate.

7. The cradle for electronic devices according to claim 5, wherein the extension part comprises a flange portion protruding from one side of the extension part to support the lower side of the support plate when the support plate slides along the cut portion and is located at the lower portion of the horizontal plate.

8. The cradle for electronic devices according to claim 1, wherein a lower plate which has a nonslip pad disposed on the lower side is joined to the lower portions of the supporters.
